(19) United States
(12) Patent Application Publication
(10) Pub. No.: US 2018/0366266 A1
(43) Pub. Date: Dec. 20, 2018

(54) Magnetically Shielded Power Inductor And Production Method

(71) Applicant: HUAWEI TECHNOLOGIES CO., LTD., Shenzhen, Guangdong (CN)

(72) Inventors: Cheng HE, Wuhan (CN); Xiaosong LIU, Shenzhen (CN); Zhiguo ZHANG, Wuhan (CN); Jie ZOU, Shenzhen (CN)

(21) Appl. No.: 16/062,694

(22) PCT Filed: Dec. 16, 2015
(86) PCT No.: PCT/CN2015/097576

§ 371 Date: Jun. 15, 2018

(51) Int. Cl. H01F 27/36; H05K 9/00; H05K 1/18

(52) U.S. Cl. CPC H01F 27/365; H05K 1/181; H05K 9/0088

(57) ABSTRACT

A magnetically shielded power inductor and a method for producing a magnetically shielded power inductor are described. The magnetically shielded power inductor includes a power inductor component and a wave-absorbing material layer. The wave-absorbing material layer is laminated on a surface of the power inductor component. The wave-absorbing material layer is configured to mitigate magnetic field interference to the power inductor component from a surrounding magnet of the wave-absorbing material layer.

### TECHNICAL FIELD

The present invention relates to the field of inductor technologies, and in particular, to a magnetically shielded power inductor and a production method.

### BACKGROUND

As a portable electronic device develops to be compact and lightweight, an ultra-thin shape of the portable electronic device imposes a stricter requirement on a size of an electronic part (for example, a surface mount power inductor) in the portable electronic device. A power inductor is also referred to as a surface mount inductor or a high current inductor. The power inductor mainly includes a magnetic core and a copper wire, mainly provides filtering and oscillation functions in a circuit, and is characterized by miniaturization, high quality, high energy storage, and low resistance. It is convenient for a user to mount the power inductor on a printed circuit board (Printed Circuit Board, PCB).

A non-magnetically shielded power inductor is prone to receive interference from an external magnetostatic field, and a magnetic field generated by the non-magnetically shielded power inductor may also cause interference to another electronic part on the PCB board. For example, during actual application, many mobile phones have accessories such as a magnetic case and a magnetic charging base. An external magnetic field generated by the magnetic case or the magnetic charging base causes magnetic field interference to an inductive device in the mobile phone. Consequently, inductance of the inductive device is reduced, a current and a voltage in a circuit of the mobile phone are affected and cannot keep stable, and a fault such as a screen flicker or a screen ripple occurs.

To resolve a problem of magnetic field interference caused to the non-magnetically shielded power inductor, currently, a magnetically shielded power inductor has the following two designs:
1. a magnetically shielded power inductor whose magnetic core is externally enclosed by a magnetic shield layer; and
2. a magnetically shielded power inductor obtained by packaging a non-shielded power inductor in a metal shielding can.

In the first magnetically shielded power inductor, the magnetic shield layer is made from a material with a high magnetic permeability, such as permalloy or a silicon steel sheet. To satisfy a magnetic saturation performance design requirement of a time-varying electromagnetic field, strict requirements are imposed on a thickness and a size of a magnetic shielding material. Currently, the magnetically shielded power inductor has an excessively large size, and is not applicable to a current smart wearable device (for example, a smart watch). In the second magnetically shielded power inductor, because shortest safe distances between devices on a PCB and between a device and a mechanical part are 0.2 mm, the solution of packaging a non-magnetically shielded power inductor in a metal shielding can is equivalent to increasing a thickness of the entire system and an area of the PCB. Consequently, a thin and light design of a portable terminal equipped with the PCB is quite difficult.

### SUMMARY

The present invention provides a magnetically shielded power inductor and a production method, so that a size and a weight of the magnetically shielded power inductor can be reduced, and a portable electronic device can be designed to be smaller and thinner. Therefore, user experience is improved.

A first aspect of the present invention provides a magnetically shielded power inductor, including:

a power inductor component and a wave-absorbing material layer, where

the wave-absorbing material layer is laminated on a surface of the power inductor component, and is configured to mitigate magnetic field interference to the power inductor component from a surrounding magnet of the wave-absorbing material layer.

With reference to the first aspect of the present invention, in a first implementation of the first aspect of the present invention, the magnetically shielded power inductor further includes a first adhesive material layer, and the first adhesive material layer is disposed on an inner surface of the wave-absorbing material layer;

the first adhesive material layer is configured to adhesively fasten the wave-absorbing material layer to the surface of the power inductor component.

With reference to the first aspect of the present invention or the first implementation of the first aspect of the present invention, in a second implementation of the first aspect of the present invention, the magnetically shielded power inductor further includes an insulation and heat-resistant coating and a second adhesive material layer, and the second adhesive material layer is disposed between the wave-absorbing material layer and the insulation and heat-resistant coating, so that the insulation and heat-resistant coating and a wave-absorbing material are laminated; and

the insulation and heat-resistant coating is configured to protect the power inductor component and the wave-absorbing material layer when the magnetically shielded power inductor is being soldered.

With reference to the first aspect of the present invention, in a third implementation of the first aspect of the present invention, the wave-absorbing material layer includes a wave-absorbing material and an adhesive material, and the adhesive material is configured to adhesively fasten the wave-absorbing material layer to the surface of the power inductor component.

With reference to the third implementation of the first aspect of the present invention, in a fourth implementation of the first aspect of the present invention, the magnetically shielded power inductor component further includes an insulation and heat-resistant coating, and the insulation and heat-resistant coating is laminated on an outer surface of the wave-absorbing material layer; and

the insulation and heat-resistant coating is configured to protect the power inductor component and the wave-absorbing material layer when the magnetically shielded power inductor is being soldered.

With reference to the first aspect of the present invention or the first implementation of the first aspect of the present invention, in a fifth implementation of the first aspect of the present invention, the wave-absorbing material layer includes a silicone substrate and a wave-absorbing dielectric, and the wave-absorbing dielectric is distributed in the silicone substrate.

With reference to the fifth implementation of the first aspect of the present invention, in a sixth implementation of the first aspect of the present invention, the wave-absorbing dielectric is at least one of ferrite, a polycrystalline iron fiber, or metal micro-powder.

With reference to the first aspect of the present invention or the sixth implementation of the first aspect of the present invention, in a seventh implementation of the first aspect of the present invention, the magnetically shielded power inductor further includes a metal shielding can, and the metal shielding can is configured to package the power inductor component and the wave-absorbing material layer.

A second aspect of the present invention provides a method for producing a magnetically shielded power inductor, including:

electroplating a surface of a power inductor component by using a primer, electroplating, by using a wave-absorbing material, the surface that has been electroplated by using the primer and that is of the power inductor component, and performing a high temperature vulcanization process on the power inductor component that has been electroplated by using the wave-absorbing material, to form a shape, where the primer includes an adhesive material.

With reference to the second aspect of the present invention, in a first implementation of the second aspect of the present invention, after the performing a high temperature vulcanization process on the power inductor component that has been electroplated by using the wave-absorbing material, to form a shape, the method includes: electroplating a surface of a wave-absorbing material layer of the power inductor component by using an insulation and heat-resistant material, and performing the high temperature vulcanization process on the power inductor component that has been electroplated by using the insulation and heat-resistant material, to form a shape.

A third aspect of the present invention provides a method for producing a magnetically shielded power inductor, including:

coating a surface of a power inductor component with an adhesive material, to form an adhesive material layer; and

coating, with a liquid wave-absorbing material, the surface that has the adhesive material layer and that is of the power inductor component, and performing curing and shaping to form a wave-absorbing material layer.

With reference to the third aspect of the present invention, in a first implementation of the third aspect of the present invention, after the performing curing and shaping to form a wave-absorbing material layer, the method further includes:

laminating an insulation and heat-resistant material on an outer surface of the wave-absorbing material layer by using an adhesive material.

It can be learned from the foregoing technical solutions that, the present invention has the following advantages:

The magnetically shielded power inductor includes the power inductor component and the wave-absorbing material layer, and the wave-absorbing material layer is laminated on the surface of the power inductor component, and is configured to mitigate the magnetic field interference to the power inductor component from the surrounding magnet of the wave-absorbing material layer. Compared with the prior art, in the magnetically shielded power inductor provided in the present invention, a magnetic shielding function is implemented by using a high magnetic permeability characteristic of the wave-absorbing material, and no metal can is required. Therefore, a size is relatively small and a weight is relatively light. In addition, because the wave-absorbing material is insulative and compressible, and does not damage a surrounding electronic part, a safe distance between devices on a PCB and a safe distance between a device and a mechanical part do not need to be additionally increased, and a portable electronic device can be designed to be smaller and thinner. Therefore, user experience is improved.

### BRIEF DESCRIPTION OF DRAWINGS

To describe the technical solutions in the embodiments of the present invention more clearly, the following briefly describes the accompanying drawings required for describing the embodiments. Apparently, the accompanying drawings in the following description show merely some embodiments of the present invention, and persons of ordinary skill in the art may still derive other drawings from these accompanying drawings without creative efforts.

FIG. 1 is a schematic structural diagram of a magnetically shielded power inductor according to an embodiment of the present invention;

FIG. 2 is another schematic structural diagram of a magnetically shielded power inductor according to an embodiment of the present invention;

FIG. 3 is another schematic structural diagram of a magnetically shielded power inductor according to an embodiment of the present invention;

FIG. 4 is another schematic structural diagram of a magnetically shielded power inductor according to an embodiment of the present invention;

FIG. 5 is a schematic flowchart of a method for producing a magnetically shielded power inductor according to an embodiment of the present invention; and

FIG. 6 is another schematic flowchart of a method for producing a magnetically shielded power inductor according to an embodiment of the present invention.

### DESCRIPTION OF EMBODIMENTS

The following clearly and completely describes the technical solutions in the embodiments of the present invention with reference to the accompanying drawings in the embodiments of the present invention. Apparently, the described embodiments are merely some rather than all of the embodiments of the present invention. All other embodiments obtained by persons skilled in the art based on the embodiments of the present invention without creative efforts shall fall within the protection scope of the present invention.

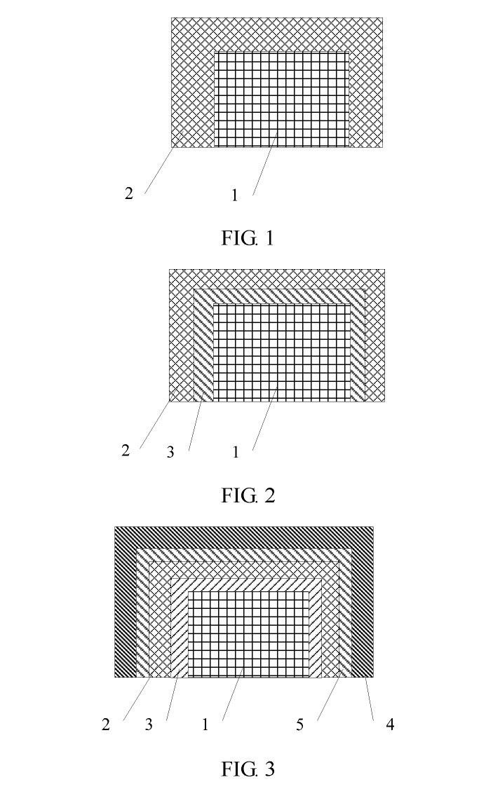

Referring to FIG. 1, an embodiment of a magnetically shielded power inductor in the embodiments of the present invention includes:

a power inductor component 1 and a wave-absorbing material layer 2.

The wave-absorbing material layer 2 is laminated on a surface of the power inductor component 1, and is configured to mitigate magnetic field interference to the power inductor component 1 from a surrounding magnet of the wave-absorbing material layer 2.

In this embodiment, the power inductor component 1 is a power inductor that does not have magnetic shielding performance or that has quite poor magnetic shielding performance.

The wave-absorbing material layer 2 includes a silicone substrate, a wave-absorbing dielectric, and an adhesive material. The wave-absorbing dielectric is distributed in the silicone substrate. The wave-absorbing dielectric is at least one of ferrite, a polycrystalline iron fiber, or metal micro-powder. The adhesive material is epoxy resin or polyurethane, or may be another adhesive material. This is not specifically limited herein.

Specifically, a magnetic permeability of a wave-absorbing material is much greater than a magnetic permeability of a non-magnetic material. The non-magnetic material includes a ceramic housing of the power inductor component or air. For example, if a relative magnetic permeability of the air is 1, a relative magnetic permeability of the ferrite is 10000. When there is a magnet outside the magnetically shielded power inductor, in the magnetically shielded power inductor in this embodiment, a high magnetic permeability characteristic of the wave-absorbing dielectric in the wave-absorbing material layer can be used, so that a significant portion of a magnetic flux of the external magnet passes through an interior of the wave-absorbing material, and a magnetic flux in space enclosed by the wave-absorbing material is small. Therefore, a magnetic shielding function is implemented.

It should be noted that, a thickness of the wave-absorbing material layer 2 is generally 0.1 mm that is far less than a device safe distance 0.2 mm, or may be another value less than the device safe distance. This is not specifically limited herein. Compared with a metal can of an existing magnetically shielded power inductor, the wave-absorbing material layer that also has the magnetic shielding function is lighter and thinner. In addition, the wave-absorbing material has good insulativity and scalability, and does not affect another electronic part on a PCB board. Compared with the prior art in which a sufficient area on the PCB board needs to be set for the metal can to ensure device safety, the magnetically shielded power inductor provided in this embodiment is smaller and lighter and occupies smaller space on the PCB board while implementing the magnetic shielding function. Therefore, user experience can be significantly improved.

Optionally, in some embodiments of the present invention, the magnetically shielded power inductor further includes an insulation and heat-resistant coating, and the insulation and heat-resistant coating is laminated on an outer surface of the wave-absorbing material layer 2. The insulation and heat-resistant coating is configured to protect the power inductor component 1 and the wave-absorbing material layer 2 when the magnetically shielded power inductor is being soldered.

Optionally, in some embodiments of the present invention, the magnetically shielded power inductor further includes a metal can, configured to package the power inductor component 1 and the wave-absorbing material layer 2.

The following uses an example in which a wave-absorbing material layer is fastened to a power inductor component by using an adhesive material layer. Referring to FIG. 2, another embodiment of a magnetically shielded power inductor in the embodiments of the present invention includes:

a power inductor component 1, a wave-absorbing material layer 2, and a first adhesive material layer 3.

The first adhesive material layer 3 is disposed on an inner surface of the wave-absorbing material layer 2, and is configured to adhesively fasten the wave-absorbing material layer 2 to a surface of the power inductor component 1.

The wave-absorbing material layer 2 is laminated on the surface of the power inductor component 1 by using the first adhesive material layer 3, and is configured to mitigate magnetic field interference to the power inductor component 1 from a surrounding magnet of the wave-absorbing material layer 2.

In this embodiment, a thickness of the first adhesive material layer 3 is generally only several micrometers, for example, 5 μm, and a thickness sum of the wave-absorbing material layer 2 and the first adhesive material layer 3 is generally 0.1 mm. It can be understood that, the thickness sum may be another value less than a device safe distance. This is not specifically limited herein. The wave-absorbing material layer 2 includes a silicone substrate and a wave-absorbing dielectric. The silicone substrate, the wave-absorbing dielectric, and an adhesive material are similar to the silicone substrate, the wave-absorbing dielectric, and the adhesive material in the embodiment shown in FIG. 1.

This embodiment provides the another magnetically shielded power inductor, so that while a magnetic shielding function is implemented, user experience can also be improved by using a design of being smaller and lighter and occupying smaller space on a PCB board. Therefore, flexibility of the embodiments of the present invention is improved.

Referring to FIG. 3, another embodiment of a magnetically shielded power inductor in the embodiments of the present invention includes:

a power inductor component 1, a wave-absorbing material layer 2, a first adhesive material layer 3, an insulation and heat-resistant coating 4, and a second adhesive material layer 5.

The first adhesive material layer 3 is disposed on an inner surface of the wave-absorbing material layer 2, and is configured to adhesively fasten the wave-absorbing material layer 2 to a surface of the power inductor component 1.

The wave-absorbing material layer 2 is laminated on the surface of the power inductor component 1 by using the first adhesive material layer 3, and is configured to mitigate magnetic field interference to the power inductor component 1 from a surrounding magnet of the wave-absorbing material layer 2.

The insulation and heat-resistant coating 4 is configured to protect the power inductor component 1, the wave-absorbing material layer 2, and the first adhesive material layer 3 when the magnetically shielded power inductor is being soldered.

The second adhesive material layer 5 is disposed between the wave-absorbing material layer 2 and the insulation and heat-resistant coating 4, so that the insulation and heat-resistant coating 4 and the wave-absorbing material layer 2 are laminated and fastened to the surface of the power inductor component.

In this embodiment, when the magnetically shielded power inductor is being soldered on a PCB board by using a wave soldering process, the insulation and heat-resistant coating 4 can protect the power inductor component 1, the wave-absorbing material layer 2, and the first adhesive material layer 3 from being affected by an external high temperature.

The insulation and heat-resistant coating 4 may be made from ceramic, rubber, or heat-resistant resin, or may be made from another insulation and heat-resistant material. This is not specifically limited herein. The wave-absorbing material layer 2 includes a silicone substrate and a wave-absorbing dielectric. The wave-absorbing material layer 2 and the adhesive material layer 3 are similar to the wave-absorbing material layer 2 and the adhesive material layer 3 in the embodiment shown in FIG. 2. Materials of the second adhesive material layer 5 and the first adhesive material layer 3 are similar.

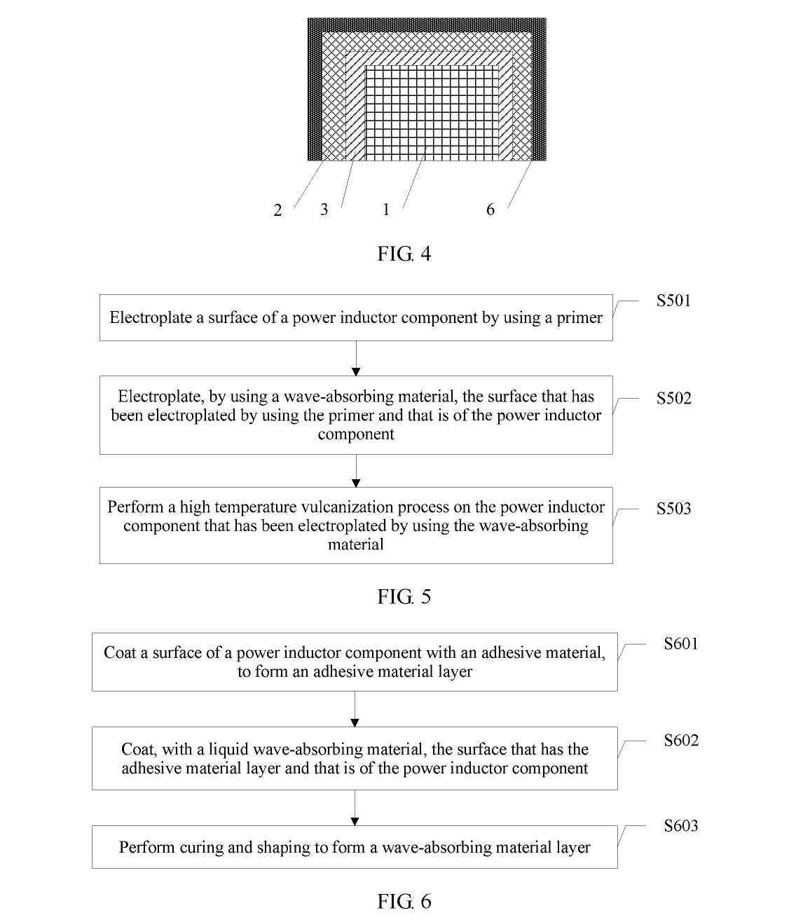

Referring to FIG. 4, another embodiment of a magnetically shielded power inductor in the embodiments of the present invention includes:

a power inductor component 1, a wave-absorbing material layer 2, an adhesive material layer 3, and a metal can 6.

The adhesive material layer 3 is configured to adhesively fasten the wave-absorbing material layer 2 to a surface of the power inductor component 1.

The wave-absorbing material layer 2 is laminated on the surface of the power inductor component 1 by using the adhesive material layer 3, and is configured to mitigate magnetic field interference to the power inductor component 1 from a surrounding magnet of the wave-absorbing material layer 2.

An insulation and heat-resistant coating 4 is laminated on an outer surface of the wave-absorbing material layer 2, and is configured to protect the power inductor component 1, the wave-absorbing material layer 2, and the adhesive material layer 3 when the magnetically shielded power inductor is being soldered.

The metal can 6 is configured to package the power inductor component 1, the wave-absorbing material layer 2, and the adhesive material layer 3.

In the magnetically shielded power inductor provided in this embodiment, the metal can 6 is disposed on an outer side of the wave-absorbing material layer 2, and double magnetic shielding is performed by using the metal can 6 and the wave-absorbing material layer 2, so that a better magnetic shielding effect can be achieved. It should be noted that, during actual application, the wave-absorbing material layer 2 and the metal can 6 may or may not be laminated. This is not limited herein. The wave-absorbing material layer 2 includes a silicone substrate and a wave-absorbing dielectric. The wave-absorbing material layer 2 and the adhesive material layer 3 are similar to the wave-absorbing material layer 2 and the adhesive material layer 3 in the embodiment shown in FIG. 2.

The foregoing describes the magnetically shielded power inductor in the embodiments of the present invention from a perspective of a product, and the following describes a method for producing a magnetically shielded power inductor. A spray-type production method is used as an example. Referring to FIG. 5, an embodiment of a method for producing a magnetically shielded power inductor in the embodiments of the present invention includes the following steps.

S501. Electroplate a surface of a power inductor component by using a primer.

The primer may include an adhesive material, and the primer is used to provide adhesion. The adhesive material may be an epoxy adhesive or a polyurethane adhesive, or may be another adhesive. This is not specifically limited herein.

Before step S501, dust removal and drying processing may be further performed on the power inductor component, to ensure that the surface of the power inductor component is clean, making it convenient to perform step S501.

S502. Electroplate, by using a wave-absorbing material, the surface that has been electroplated by using the primer and that is of the power inductor component.

After being electroplated by using the primer, the surface of the power inductor component is electroplated by using the wave-absorbing material, to form a wave-absorbing material layer on the surface of the power inductor. The wave-absorbing material includes a substrate and a wave-absorbing dielectric. The substrate is a silicone substrate. The wave-absorbing dielectric is ferrite, a polycrystalline iron fiber, or metal micro-powder, or may be another wave-absorbing material. This is not limited herein.

S503. Perform a high temperature vulcanizing process on the power inductor component that has been electroplated by using the wave-absorbing material.

High temperature vulcanization is a technology of shaping a product at a temperature of 165° C. to 180° C. by using a crosslinking attribute of a vulcanizing agent. By means of the high temperature vulcanization process, the wave-absorbing material can be firmly fastened to the surface of the power inductor component, and then, the power inductor component is cooled to a normal temperature to obtain a finished magnetically shielded power inductor product.

Optionally, in some embodiments of the present invention, after the performing a high temperature vulcanization process on the power inductor component that has been electroplated by using the wave-absorbing material, to form a shape, the method includes: electroplating a surface of the wave-absorbing material layer of the power inductor component by using an insulation and heat-resistant material, and performing the high temperature vulcanization process on the power inductor component that has been electroplated by using the insulation and heat-resistant material, to form a shape.

Specifically, after being electroplated by using the wave-absorbing material, the surface of the power inductor component is electroplated by using the insulation and heat-resistant material, to form an insulation and heat-resistant layer on the surface of the power inductor, and finally, the high temperature vulcanization process is performed, so that the insulation and heat-resistant material and the wave-absorbing material are firmly fastened to the surface of the power inductor component, to obtain a finished, insulative, and high temperature-resistant magnetically shielded power inductor product. A thickness of the insulation and heat-resistant layer is generally 40 μm to 50 μm. The insulation and heat-resistant material may be rubber, heat-resistant resin, ceramic, or another material that has insulation and heat-resistant performance. This is not limited herein.

Optionally, in some embodiments of the present invention, after the performing a high temperature vulcanization process on the power inductor component that has been electroplated by using the wave-absorbing material, to form a shape, the method includes: electroplating a surface of the wave-absorbing material layer of the power inductor component by using a top coating.

Specifically, the top coating has characteristics of stain resistance, aging resistance, and moisture resistance, and decoration and protection functions can be implemented by electroplating the wave-absorbing material layer of the power inductor component by using the top coating. The top coating may be a polyester-polyurethane resin top coating, or may be a top coating of another material. This is not limited herein.

Optionally, in some embodiments of the present invention, after the performing a high temperature vulcanization process on the power inductor component that has been electroplated by using the wave-absorbing material, to form a shape, the method includes: electroplating a surface of the insulation and heat-resistant layer of the power inductor component by using a top coating.

Specifically, decoration and protection functions can be implemented by electroplating the surface of the insulation and heat-resistant layer of the power inductor component by using the top coating. A specific process is similar to the process of electroplating the surface of the wave-absorbing material layer by using the top coating. Refer to the foregoing embodiment, and details are not described herein again.

The spray-type production method provided in the present invention may be further applied to another object. For example, the spray-type method is used to electroplate one or more surfaces of a magnet by using a wave-absorbing material, so that magnetic attraction of the surface that is of the magnet and that is coated with the wave-absorbing material is reduced. Alternatively, the spray-type method is used to electroplate an inner surface of a housing of a power supply by using a wave-absorbing material, to avoid magnetic interference from an external magnetic field of the power supply to an electronic part in the power supply.

For ease of understanding, the following describes, in detail by using a specific application scenario, the method for producing a magnetically shielded power inductor in this embodiment of the present invention:

For example, an adhesive material is an epoxy adhesive. A wave-absorbing material includes a silicone substrate and a manganese-zinc soft ferrite powder. First, dust removal and drying are performed on a power inductor, and a surface of the power inductor component is electroplated by using a primer, and plated with a film (by using a wave-absorbing material), and then, high temperature vulcanization is performed to form a shape, to obtain a magnetically shielded power inductor. This magnetically shielded power inductor has only a quite thin wave-absorbing material layer on the surface, and can effectively mitigate magnetostatic field interference generated by an external magnet (for example, a magnet in a magnetic case or a magnet in a magnetic charging base).

Optionally, after film plating, the surface of the power inductor component may be electroplated by using an insulation and heat-resistant material, and high temperature vulcanization is performed to form a shape. This magnetically shielded power inductor has insulativity and heat resistance, and may be applied to a process of soldering a power inductor on a PCB board.

The following describes a method for producing a magnetically shielded power inductor by using a coating-type production method as an example. Referring to FIG. 6, another embodiment of a method for producing a magnetically shielded power inductor in the embodiments of the present invention includes the following steps.

S601. Coat a surface of a power inductor component with an adhesive material, to form an adhesive material layer.

In this embodiment, a hair brush may be used to coat the surface of the power inductor component with the adhesive material. The adhesive material can provide adhesion, and may be an epoxy adhesive or a polyurethane adhesive, or may be another adhesive. This is not specifically limited herein. A thickness of the adhesive material layer is generally 5 μm (micrometer), and tensile strength is 0.3 MPa. Alternatively, a thickness of the adhesive material layer may be another value. This is not limited herein.

Before step S601, dust removal and drying processing may be further performed on the power inductor component, to ensure that the surface of the power inductor component is clean, making it convenient to perform step S601.

S602. Coat, with a liquid wave-absorbing material, the surface that has the adhesive material layer and that is of the power inductor component.

Specifically, the surface that has the adhesive material layer and that is of the power inductor component is coated, by means of a gel dispensing process, with the liquid wave-absorbing material that is placed in a dispenser.

During actual application, multiple power inductor components may be fastened in a straight line by using a pallet, and gel dispensing is performed on the multiple power inductor components in sequence by using the dispenser.

S603. Perform curing and shaping to form a wave-absorbing material layer.

Specifically, the power inductor component coated with the wave-absorbing material is laid aside for a period of time, and after the liquid wave-absorbing material is cured and shaped to form the wave-absorbing material layer, a magnetically shielded power inductor is obtained.

It should be noted that, because the liquid wave-absorbing material forms different shapes in a curing and shaping process, a cutter may be further used to shave the magnetically shielded power inductor on which the wave-absorbing material layer is formed.

It should be noted that, in this embodiment, the adhesive material and the wave-absorbing material may be separately used for coating, or may be used for coating after the materials are mixed. This is not specifically limited herein.

Optionally, in some embodiments of the present invention, the method further includes:

coating, with an adhesive material, an inner surface of a mold that fits a size of the power inductor component, and/or on an outer surface of the wave-absorbing material layer; and

interlocking the mold and the power inductor component that has the wave-absorbing material layer.

Specifically, the adhesive material may adhesively fasten the mold that is made from an insulation and heat-resistant material and the power inductor that has the wave-absorbing material layer together. After the adhesive material is cured, a magnetically shielded power inductor having insulation and heat-resistant performance is produced.

In the magnetically shielded power inductor in this embodiment, the wave-absorbing material is between the power inductor component and an insulation and heat-resistant layer, and the insulation and heat-resistant layer is located at an outer layer. A thickness of the insulation and heat-resistant layer is generally 40 μm to 50 μm, and a specific value is not limited herein.

The coating-type production method provided in the present invention may be further applied to another object. For example, the coating-type method is used to laminate a magnetic shielding film on one or more surfaces of a magnet, so that magnetic attraction of the surface that is of the magnet and that is coated with the magnetic shielding film is reduced. Alternatively, the coating-type method is used to coat an inner surface of a housing of a power supply with a magnetic shielding film, to avoid magnetic interference from an external magnetic field of the power supply to an electronic part in the power supply.

For ease of understanding, the following describes, in detail by using a specific application scenario, the method for producing a magnetically shielded power inductor in this embodiment of the present invention:

For example, an adhesive material is an epoxy adhesive. A wave-absorbing material includes a silicone substrate and a manganese-zinc soft ferrite powder. Dust removal and drying are performed on a power inductor, and a surface of the power inductor is coated with the epoxy adhesive. Then, the surface that has the epoxy adhesive and that is of the power inductor is coated with the wave-absorbing material by means of a gel dispensing process, to obtain a magnetically shielded power inductor. This magnetically shielded power inductor has only a quite thin wave-absorbing material layer on the surface, and therefore has a quite small size, is applicable to a lightweight portable electronic device, and can effectively mitigate magnetostatic field interference generated by an external magnet (for example, a magnet in a magnetic case or a magnet in a magnetic charging base).

Optionally, a housing mold, for example, a ceramic housing, of the power inductor component may be further produced by using an insulation and heat-resistant material. After an inner surface of the mold is coated with an adhesive material, the power inductor component is interlocked with the mold. After the adhesive material is cured, a magnetically shielded power inductor is obtained. This magnetically shielded power inductor has insulativity and heat resistance, and may be applied to a process of soldering a power inductor on a PCB board.

The foregoing embodiments are merely intended for describing the technical solutions of the present invention, but not for limiting the present invention. Although the present invention is described in detail with reference to the foregoing embodiments, persons of ordinary skill in the art should understand that they may still make modifications to the technical solutions described in the foregoing embodiments or make equivalent replacements to some technical features thereof, without departing from the spirit and scope of the technical solutions of the embodiments of the present invention.

1. A magnetically shielded power inductor, comprising:
a power inductor component and a wave-absorbing material layer, wherein the wave-absorbing material layer is laminated on a surface of the power inductor component, and wherein the wave-absorbing material layer is configured to mitigate magnetic field interference to the power inductor component from a surrounding magnet of the wave-absorbing material layer.

2. The magnetically shielded power inductor according to claim 1, further comprising a first adhesive material layer, wherein the first adhesive material layer is disposed on an inner surface of the wave-absorbing material layer, and wherein the first adhesive material layer is configured to adhesively fasten the wave-absorbing material layer to the surface of the power inductor component.

3. The magnetically shielded power inductor according to claim 1, further comprising an insulation and heat-resistant coating and a second adhesive material layer, wherein:
the second adhesive material layer is disposed between the wave-absorbing material layer and the insulation and heat-resistant coating to laminate the insulation and heat-resistant coating and the wave-absorbing material layer; and
the insulation and heat-resistant coating is configured to protect the power inductor component and the wave-absorbing material layer when the magnetically shielded power inductor is being soldered.

4. The magnetically shielded power inductor according to claim 1, wherein the wave-absorbing material layer comprises a wave-absorbing material and an adhesive material, and wherein the adhesive material is configured to adhesively fasten the wave-absorbing material layer to the surface of the power inductor component.

5. The magnetically shielded power inductor according to claim 4, further comprising an insulation and heat-resistant coating, wherein the insulation and heat-resistant coating is laminated on an outer surface of the wave-absorbing material layer, and wherein the insulation and heat-resistant coating is configured to protect the power inductor component and the wave-absorbing material layer when the magnetically shielded power inductor is being soldered.

6. The magnetically shielded power inductor according to claim 1, wherein the wave-absorbing material layer comprises a silicone substrate and a wave-absorbing dielectric, and wherein the wave-absorbing dielectric is distributed in the silicone substrate.

7. The magnetically shielded power inductor according to claim 6, wherein the wave-absorbing dielectric is at least one of ferrite, a polycrystalline iron fiber, or metal micro-powder.

8. The magnetically shielded power inductor according to claim 1, further comprising a metal shielding can, wherein the metal shielding can is configured to package the power inductor component and the wave-absorbing material layer.

9. A method for producing a magnetically shielded power inductor, comprising:
electroplating a surface of a power inductor component by using a primer, wherein the primer comprises an adhesive material;
electroplating, by using a wave-absorbing material, the surface of the power inductor component that has been electroplated by using the primer; and
performing a high temperature vulcanization process on the power inductor component that has been electroplated by using the wave-absorbing material to form a shape.

10. The method according to claim 9, wherein the performing a high temperature vulcanization process on the power inductor component that has been electroplated by using the wave-absorbing material to form a shape comprises:
electroplating a surface of the wave-absorbing material of the power inductor component by using an insulation and heat-resistant material; and
performing the high temperature vulcanization process on the power inductor component that has been electroplated by using the insulation and heat-resistant material to form the shape.

11. A method for producing a magnetically shielded power inductor, comprising:
coating a surface of a power inductor component with an adhesive material to form an adhesive material layer;
coating, with a liquid wave-absorbing material, the surface of the power inductor component that has the adhesive material layer; and
performing curing and shaping to form a wave-absorbing material layer of the magnetically shielded power inductor.

12. The method according to claim 11, further comprising:
coating, with an adhesive material, at least one of an inner surface of a mold that fits a size of the power inductor component or an outer surface of the wave-absorbing material layer; and
interlocking the mold and the power inductor component that has the wave-absorbing material layer.

13. The magnetically shielded power inductor according to claim 2, further comprising an insulation and heat-resistant coating and a second adhesive material layer, wherein the second adhesive material layer is disposed between the wave-absorbing material layer and the insulation and heat-resistant coating to laminate the insulation and heat-resistant coating and the wave-absorbing material layer; and
the insulation and heat-resistant coating is configured to protect the power inductor component and the wave-absorbing material layer when the magnetically shielded power inductor is being soldered.

14. The magnetically shielded power inductor according to claim 2, wherein the wave-absorbing material layer comprises a silicone substrate and a wave-absorbing dielectric, and wherein the wave-absorbing dielectric is distributed in the silicone substrate.

15. The magnetically shielded power inductor according to claim 14, wherein the wave-absorbing dielectric is at least one of ferrite, a polycrystalline iron fiber, or metal micro-powder.

16. The magnetically shielded power inductor according to claim 2, further comprising a metal shielding can, wherein the metal shielding can is configured to package the power inductor component and the wave-absorbing material layer.
